(19) United States
(12) Patent Application Publication
(10) Pub. No.: US 2023/0275035 A1
(43) Pub. Date: Aug. 31, 2023

(54) SEMICONDUCTOR MODULE, METHOD FOR MANUFACTURING THE SAME, AND POWER CONVERSION DEVICE

(71) Applicant: Mitsubishi Electric Corporation, Chiyoda-ku, Tokyo (JP)

(72) Inventors: Hiroyuki YOSHIHARA, Chiyoda-ku, Tokyo (JP); Yusuke ISHIYAMA, Chiyoda-ku, Tokyo (JP); Yasuyuki SANDA, Chiyoda-ku, Tokyo (JP); Kenichi HAYASHI, Chiyoda-ku, Tokyo (JP)

(73) Assignee: Mitsubishi Electric Corporation, Chiyoda-ku, Tokyo (JP)

(21) Appl. No.: 18/043,605

(22) PCT Filed: Sep. 14, 2021
(86) PCT No.: PCT/JP2021/033772

§ 371 Date: Mar. 1, 2023

(30) Foreign Application Priority Data
Sep. 25, 2020 (JP) 2020-160283

(51) Int. Cl. H01L 23/00; H01L 23/31; H01L 23/495; H01L 21/48; H01L 21/56

(52) U.S. Cl. CPC H01L 23/562; H01L 23/3107; H01L 23/4952; H01L 23/49568; H01L 23/49575; H01L 21/4825; H01L 21/4882; H01L 21/565; H02P 27/08

(57) ABSTRACT

A semiconductor module includes: a fin base including a first surface and a second surface, the second surface being a surface opposite to the first surface; an insulating sheet arranged on the first surface; a plurality of frame patterns arranged on the first surface with the insulating sheet interposed therebetween; a semiconductor element arranged on at least one of the plurality of frame patterns; and a plurality of fins swaged onto the second surface so as to be spaced apart from each other in a first direction.

### TECHNICAL FIELD

The present disclosure relates to a semiconductor module, a method for manufacturing the same, and a power conversion device.

### BACKGROUND ART

WO 2015/046040 (PTL 1) describes a heat sink integrated power module. The heat sink integrated power module described in PTL 1 includes a fin base, a first fin and a second fin, an insulating sheet, a lead frame, a power semiconductor element, and a mold resin.

The fin base includes a first surface and a second surface that is a surface opposite to the first surface. The insulating sheet is arranged on the first surface. A part of the lead frame is arranged on the insulating sheet (hereinafter, the part of the lead frame arranged on the first surface will be referred to as “frame pattern”). The power semiconductor element is arranged on the frame pattern. The lead frame includes an external terminal.

The second surface is provided with a first fin insertion groove and a second fin insertion groove. The first fin insertion groove and the second fin insertion groove extend along a first direction and are spaced apart from each other in a second direction orthogonal to the first direction. A swaging portion is formed between the first fin insertion groove and the second fin insertion groove. An upper surface of the swaging portion is provided with a groove (hereinafter, referred to as “swaging groove”) extending along the first direction.

The first fin and the second fin are swaged by the swaging portion. The mold resin seals the fin base, the lead frame, the insulating sheet, and the power semiconductor element such that the external terminal and the second surface are exposed from the mold resin.

### CITATION LIST

### Patent Literature

PTL 1: WO 2015/046040

### SUMMARY OF INVENTION

### Technical Problem

When a jig is inserted into the swaging groove, the swaging portion is plastically deformed and a width of the swaging groove is expanded along the second direction. As a result, the first fin and the second fin are swaged by the swaging portion.

Due to heat shrinkage of the mold resin, the heat sink integrated power module described in PTL 1 may be warped convexly along a direction from the first surface toward the second surface, before the first fin and the second fin are attached.

The above-described warp is forcibly flattened by a load when the jig is inserted into the swaging groove. In this case, it is concerned that separation may occur between an end of the frame pattern and the insulating sheet or a crack may occur in the insulating sheet due to the bending stress caused by the flattening of the warp. The separation of the insulating sheet and the crack in the insulating sheet lead to a deterioration of the insulation property of the heat sink integrated power module described in PTL 1.

The present disclosure has been made in light of the above-described problems of the conventional art. More specifically, the present disclosure provides a semiconductor module capable of suppressing a deterioration of the insulation property caused by separation of an insulating sheet or occurrence of a crack in the insulating sheet.

### Solution to Problem

A semiconductor module according to the present disclosure includes: a fin base including a first surface and a second surface, the second surface being a surface opposite to the first surface; an insulating sheet arranged on the first surface; a plurality of frame patterns arranged on the first surface with the insulating sheet interposed therebetween; a semiconductor element arranged on at least one of the plurality of frame patterns; and a plurality of fins swaged onto the second surface so as to be spaced apart from each other in a first direction. The second surface is provided with a plurality of rising wall portions and a plurality of swaging portions, the plurality of rising wall portions extending along a second direction that intersects with the first direction and being spaced apart from each other in the first direction, each of the plurality of swaging portions extending along the second direction between adjacent two of the plurality of rising wall portions. At least one of the plurality of swaging portions includes a contact portion and a spaced-apart portion, the contact portion being in contact with a corresponding one of the plurality of fins, the spaced-apart portion being spaced apart from the corresponding one of the plurality of fins.

### Advantageous Effects of Invention

According to the semiconductor module of the present disclosure, it is possible to suppress a deterioration of the insulation property caused by separation of an insulating sheet or occurrence of a crack in the insulating sheet.

### BRIEF DESCRIPTION OF DRAWINGS

FIG. 1 is a plan view of a semiconductor module 100.

FIG. 2 is a cross-sectional view taken along II-II in FIG. 1.

FIG. 3 is a bottom view of semiconductor module 100.

FIG. 4 is a cross-sectional view taken along IV-IV in FIG. 3.

FIG. 5 is a cross-sectional view of a frame pattern 41 in the vicinity of an end.

FIG. 6 is a flowchart showing a method for manufacturing semiconductor module 100.

FIG. 7 is a schematic cross-sectional view for illustrating a swaging step S5.

FIG. 8 is a cross-sectional view of a swaging blade 200 parallel to a second direction DR2.

FIG. 9 is a bottom view of a semiconductor module 100A.

FIG. 10 is a plan view of a semiconductor module 100B.

FIG. 11 is a cross-sectional view taken along XI-XI in FIG. 10.

FIG. 12 is a plan view of a semiconductor module 100C.

FIG. 13 is a cross-sectional view taken along XIII-XIII in FIG. 12.

FIG. 14 is a block diagram showing a configuration of a power conversion system 300.

### DESCRIPTION OF EMBODIMENTS

Embodiments of the present disclosure will be described with reference to the drawings, in which the same or corresponding portions are denoted by the same reference characters and redundant description will not be repeated.

### First Embodiment

A semiconductor module (hereinafter, referred to as “semiconductor module 100”) according to a first embodiment will be described below.

<Configuration of Semiconductor Module 100>

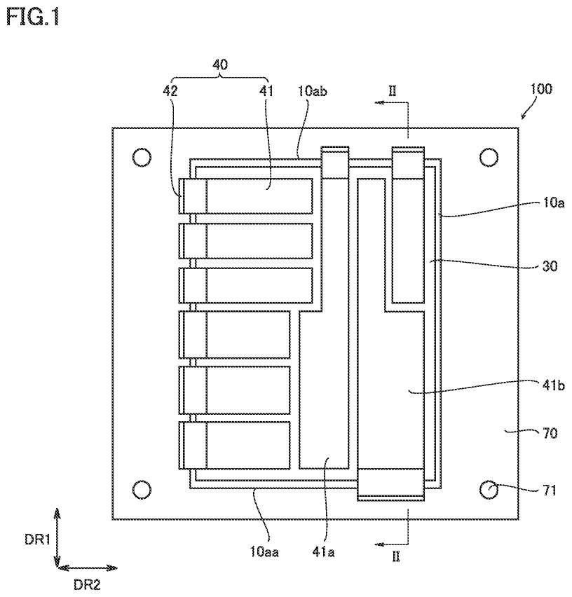

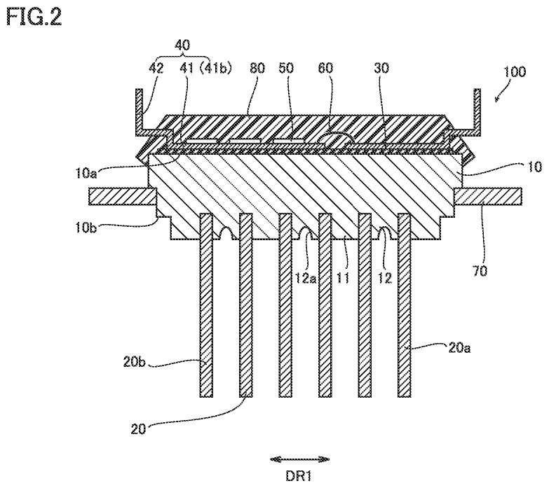

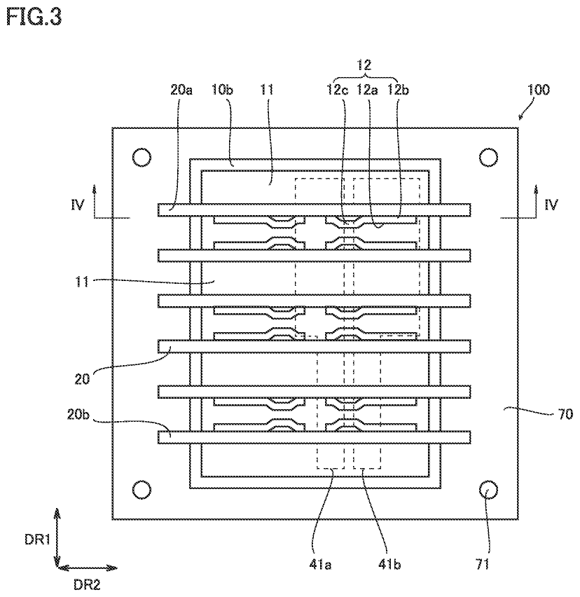

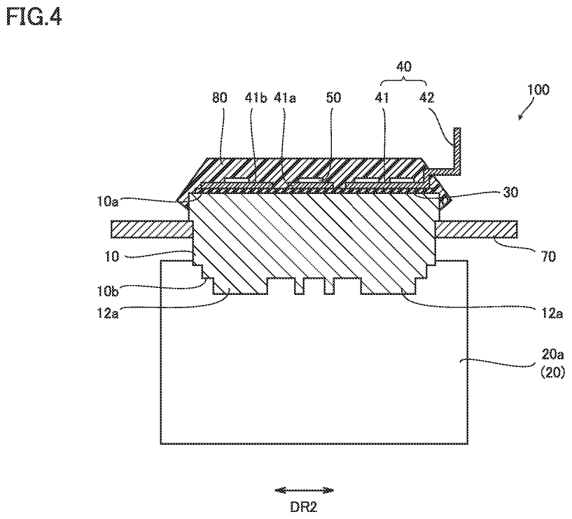

FIG. 1 is a plan view of semiconductor module 100. In FIG. 1, a semiconductor element 50, a wire 60 and a mold resin 80 are not shown. FIG. 2 is a cross-sectional view taken along II-II in FIG. 1. FIG. 3 is a bottom view of semiconductor module 100. In FIG. 3, a frame pattern 41a and a frame pattern 41b are indicated by dotted lines. FIG. 4 is a cross-sectional view taken along IV-IV in FIG. 3.

As shown in FIGS. 1, 2, 3, and 4, semiconductor module 100 includes a fin base 10, a plurality of fins 20, an insulating sheet 30, a lead frame 40, semiconductor element 50, wire 60, a panel 70, and mold resin 80.

Fin base 10 includes a first surface 10a and a second surface 10b. First surface 10a and second surface 10b are end surfaces of fin base 10 in a thickness direction. Second surface 10b is a surface opposite to first surface 10a. Fin base 10 is made of, for example, a metal material. Examples of the metal material include aluminum, aluminum alloy, copper, copper alloy and the like. Fin base 10 has a rectangular shape in a plan view (when viewed from a direction orthogonal to first surface 10a).

First surface 10a includes a first end 10aa and a second end 10ab in a first direction DR1. Second end 10ab is an end opposite to first end 10aa. First direction DR1 is along a longitudinal direction of fin base 10.

Second surface 10b is provided with a plurality of rising wall portions 11 and a plurality of swaging portions 12. Rising wall portions 11 extend along a second direction DR2. Second direction DR2 is a direction that intersects with (preferably, is orthogonal to) first direction DR1. The plurality of rising wall portions 11 are spaced apart from each other in first direction DR1. Rising wall portions 11 rise from second surface 10b along a direction from first surface 10a toward second surface 10b.

Each of the plurality of swaging portions 12 extends along second direction DR2 between adjacent two of rising wall portions 11. Swaging portions 12 rise from second surface 10b along the direction from first surface 10a toward second surface 10b. An upper surface of each of swaging portions 12 is provided with a groove 12a. Groove 12a extends along second direction DR2. Details of swaging portions 12 will be described below.

Each of fins 20 has a flat plate shape. A thickness direction of fin 20 is along first direction DR1. The plurality of fins 20 are spaced apart from and adjacent to each other in first direction DR1. Fins 20 extend along second direction DR2 in a plan view. Fins 20 are made of, for example, a metal material. Examples of the metal material include aluminum, aluminum alloy, copper, copper alloy and the like. Each of fins 20 is arranged between rising wall portion 11 and swaging portion 12 that are adjacent to each other.

Each of fins 20 extends such that both ends thereof in second direction DR2 protrude from an outer edge of fin base 10 in a plan view. However, each of fins 20 is located inside an outer edge of panel 70 in a plan view.

Insulating sheet 30 is arranged on first surface 10a. Insulating sheet 30 is made of an insulating material. Examples of the insulating material include a resin material.

Lead frame 40 is made of, for example, a metal material. Examples of the metal material include aluminum, aluminum alloy, copper, copper alloy and the like. Lead frame 40 includes a frame pattern 41 and a terminal portion 42. Frame pattern 41 is arranged on first surface 10a with insulating sheet 30 interposed therebetween. Terminal portion 42 is a portion used for connection to an external device. Frame pattern 41 is located closer to first surface 10a than terminal portion 42. That is, a height difference is formed between frame pattern 41 and terminal portion 42.

Frame patterns 41 arranged on a central portion of first surface 10a are referred to as “frame pattern 41a” and “frame pattern 41b”. Frame pattern 41a and frame pattern 41b extend along first direction DR1. Frame pattern 41a and frame pattern 41b are spaced apart from and adjacent to each other in second direction DR2. This space is preferably greater than a thickness of frame pattern 41a (frame pattern 41b).

Fin 20 located closest to first end 10aa is referred to as “fin 20a”. Fin 20 located closest to second end 10ab is referred to as “fin 20b”. Both ends of each of frame pattern 41a and frame pattern 41b in first direction DR1 are located outside fin 20a and fin 20b. That is, the end of frame pattern 41a on the first end 10aa side and the end of frame pattern 41b on the first end 10aa side are located closer to first end 10aa than fin 20a, and the end of frame pattern 41a on the second end 10ab side and the end of frame pattern 41b on the second end 10ab side are located closer to second end 10ab than fin 20b.

Frame pattern 41 includes portions located outside rising wall portion 11 (swaging portion 12) located closest to first end 10aa and rising wall portion 11 (swaging portion 12) located closest to second end 10ab. Frame pattern 41 may be located inside rising wall portion 11 (swaging portion 12) located closest to first end 10aa and rising wall portion 11 (swaging portion 12) located closest to second end 10ab.

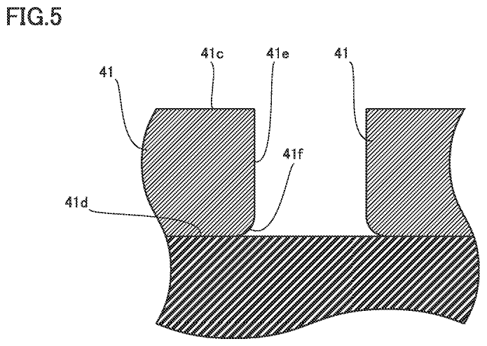

FIG. 5 is a cross-sectional view of frame pattern 41 in the vicinity of the end. As shown in FIG. 5, frame pattern 41 includes a first surface 41c, a second surface 41d and a side surface 41e. First surface 41c and second surface 41d are end surfaces of frame pattern 41 in a thickness direction. First surface 41c is a surface on the semiconductor element 50 side. Second surface 41d is a surface opposite to first surface 41c and is a surface on the insulating sheet 30 side. Side surface 41e is continuous to first surface 41c and second surface 41d. An intersecting ridge line of second surface 41d and side surface 41e is referred to as “corner portion 41f”. Corner portion 41f is preferably formed by a curved surface.

Semiconductor element 50 is formed on a semiconductor substrate. The semiconductor substrate is made of silicon or a material (such as, for example, silicon carbide, gallium nitride or diamond) having a bandgap wider than that of silicon. Semiconductor element 50 is arranged on frame pattern 41. Connection between semiconductor element 50 and frame pattern 41 is made by, for example, solder (not shown).

Semiconductor element 50 is a switching element such as a metal oxide semiconductor field effect transistor (MOSFET) or an insulated gate bipolar transistor (IGBT). Semiconductor element 50 may be a rectifying element such as a schottky barrier diode or a fast recovery diode. That is, semiconductor element 50 is a power semiconductor element. Semiconductor element 50 may be a control element for controlling the above-described power semiconductor element.

Wire 60 connects a plurality of frame patterns 41. A plurality of semiconductor elements 50 are thereby electrically connected to each other. Wire 60 is made of, for example, a metal material. Examples of the metal material include aluminum, aluminum alloy, copper, copper alloy, gold and the like.

Panel 70 has a flat plate shape. Panel 70 is attached to a surface of fin base 10 on the fin 20 side so as to surround fin base 10. Panel 70 is provided with a hole 71. Hole 71 passes through panel 70 in a thickness direction. Semiconductor module 100 is fixed to a housing of another device (not shown) by inserting a fixing member such as a screw (not shown) into hole 71 and screwing semiconductor module 100 to the housing. Thus, the housing and panel 70 form a wind path and the wind from an air-cooling fan can flow through the wind path to thereby air-cool fins 20.

Mold resin 80 is made of an insulating resin material. Examples of the insulating resin material include a thermosetting resin such as an epoxy resin. The insulating resin material may be a thermoplastic resin having a high hardness, such as polyphenylene sulfide. Mold resin 80 seals fin base 10, insulating sheet 30, lead frame 40, semiconductor element 50, and wire 60 such that second surface 10b and terminal portion 42 are exposed.

<Details of Swaging Portions 12>

Each of swaging portions 12 includes a contact portion 12b and a spaced-apart portion 12c. Contact portion 12b is a portion that is in contact with fin 20. Spaced-apart portion 12c is a portion that is spaced apart from fin 20. From another point of view, contact portion 12b is a portion that is plastically deformed, and spaced-apart portion 12c is a portion that is not plastically deformed. That is, fin 20 is swaged between contact portion 12b and rising wall portion 11, and fin 20 is not swaged between spaced-apart portion 12c and rising wall portion 11.

Spaced-apart portion 12c is arranged at a position that overlaps with the space between frame pattern 41a and frame pattern 41b in a plan view. A length of contact portion 12b in second direction DR2 is referred to as “first length”, and a length of spaced-apart portion 12c in second direction DR2 is referred to as “second length”. A value obtained by dividing the second length by the first length is preferably not less than 0.3 and not more than 0.6. Although contact portion 12b and spaced-apart portion 12c are integrally formed in the example shown in FIGS. 1 to 4, contact portion 12b and spaced-apart portion 12c may be separated from each other.

<Method for Manufacturing Semiconductor Module 100>

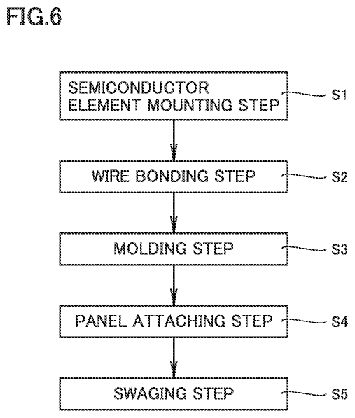

FIG. 6 is a flowchart showing a method for manufacturing semiconductor module 100. As shown in FIG. 6, the method for manufacturing semiconductor module 100 includes a semiconductor element mounting step S1, a wire bonding step S2, a molding step S3, a panel attaching step S4, and a swaging step S5.

In semiconductor element mounting step S1, firstly, solder is arranged on frame pattern 41. Secondly, with semiconductor element 50 arranged on the solder, the solder is heated and melted. Thereafter, cooling is performed, and connection between semiconductor element 50 and frame pattern 41 is thereby established by the solder. In wire bonding step S2, wire bonding between adjacent frame patterns 41 is performed by using wire 60.

In molding step S3, mold resin 80 is formed. Mold resin 80 is formed by, for example, transfer molding. More specifically, firstly, semiconductor module 100 that has completed wire bonding step S2 is arranged in a die, together with fin base 10 including insulating sheet 30 on first surface 10a. Secondly, the die is filled with the resin material and the resin material is cured.

Due to heat shrinkage of mold resin 80 after semiconductor module 100 is taken out from the die, an upper surface of mold resin 80 in semiconductor module 100 may be warped convexly in a downward direction (convexly in a direction from first surface 10a toward second surface 10b). However, regardless of this direction of the warp, semiconductor module 100 produces the similar effect.

In panel attaching step S4, panel 70 is swaged and fixed to the surface of fin base 10 on the fin 20 side.

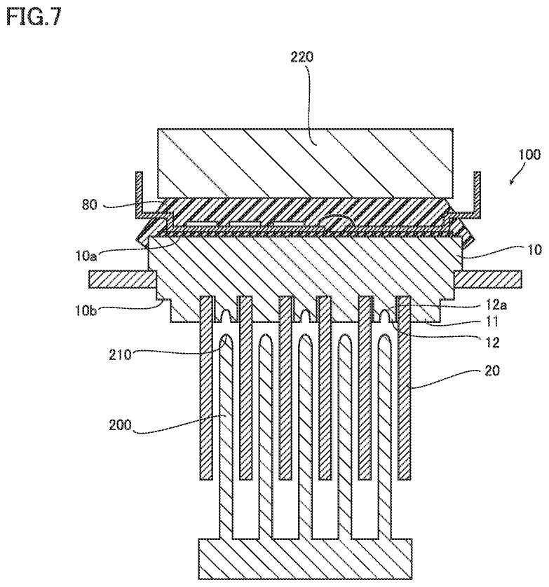

In swaging step S5, fin 20 is swaged onto first surface 10a. In swaging step S5, fin 20 is firstly arranged between rising wall portion 11 and swaging portion 12. FIG. 7 is a schematic cross-sectional view for illustrating swaging step S5. As shown in FIG. 7, in swaging step S5, fin 20 is secondly swaged by rising wall portion 11 and swaging portion 12.

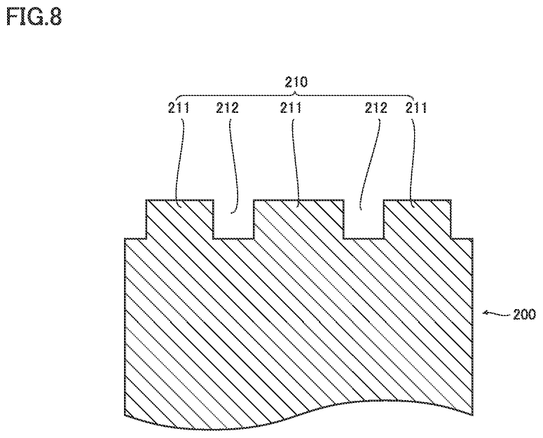

The swaging is performed using a swaging blade 200. FIG. 8 is a cross-sectional view of swaging blade 200 parallel to second direction DR2. As shown in

FIG. 8, swaging blade 200 includes a tip 210. Tip 210 includes a first portion 211 and a second portion 212. A width of first portion 211 in first direction DR1 is greater than a width of groove 12a in first direction DR1. A width of second portion 212 in first direction DR1 is smaller than a width of groove 12a in first direction DR1. In the example shown in FIG. 8, second portion 212 is a notch, and thus, the width of second portion 212 in first direction DR1 is zero and is smaller than the width of groove 12a in first direction DR1.

Tip 210 is inserted into groove 12a. As described above, the width of first portion 211 in first direction DR1 is greater than the width of groove 12a in first direction DR1, and thus, in a portion where first portion 211 is inserted, swaging portion 12 is plastically deformed toward the fin 20 side, to thereby swage fin 20. That is, the portion where first portion 211 is inserted forms contact portion 12b.

In contrast, the width of second portion 212 in first direction DR1 is greater than the width of groove 12a in first direction DR1, and thus, in a portion where second portion 212 is inserted, swaging portion 12 is not deformed toward the fin 20 side. That is, the portion where second portion 212 is inserted forms spaced-apart portion 12c.

When tip 210 is inserted into groove 12a, a load from a punch 220 is applied to semiconductor module 100 along a direction opposite to the direction of insertion of tip 210 from the mold resin 80 side. The warp of mold resin 80 is flattened by this load.

<Effects of Semiconductor Module 100>

As described above, due to heat shrinkage of mold resin 80, semiconductor module 100 before swaging of fin 20 is warped. The warp is flattened by the load from swaging blade 200 and punch 220 when fin 20 is swaged onto second surface 10b. It is concerned that separation may occur between the end of frame pattern 41 and insulating sheet 30 or a crack may occur in insulating sheet 30 due to the bending stress caused by the flattening.

However, in semiconductor module 100, swaging portion 12 includes spaced-apart portion 12c (tip 210 includes second portion 212). Therefore, even when the load from swaging blade 200 and punch 220 is small, a surface pressure required to plastically deform contact portion 12b can be ensured. Therefore, according to semiconductor module 100, the bending stress that occurs during the above-described flattening is reduced and a deterioration of the insulation property caused by the separation between the end of frame pattern 41 and insulating sheet 30 or the occurrence of a crack in insulating sheet 30 is suppressed.

The bending stress that occurs during the above-described flattening has a remarkable influence on frame pattern 41a and frame pattern 41b. When frame pattern 41a and frame pattern 41b are spaced apart from each other in second direction DR2 and spaced-apart portion 12c is arranged at the position that overlaps with this space in a plan view, it is possible to suppress the separation of insulating sheet 30 or the occurrence of a crack in insulating sheet 30 at a location where stress concentration is likely to occur.

When the value obtained by dividing the second length by the first length is not less than 0.3 and not more than 0.6, it is possible to suppress a deterioration of the insulation property caused by the separation of insulating sheet 30 or the occurrence of a crack in insulating sheet 30, while ensuring the sufficient fixing force for swaging fin 20.

When contact portion 12b and spaced-apart portion 12c are formed to be separated from each other, plastic deformation of contact portion 12b is likely to occur, and thus, the load when swaging fin 20 can be further reduced. As a result, it is possible to further suppress a deterioration of the insulation property caused by the separation of insulating sheet 30 or the occurrence of a crack in insulating sheet 30.

### Second Embodiment

A semiconductor module according to a second embodiment (hereinafter, referred to as “semiconductor module 100A”) will be described below. A difference from semiconductor module 100 will be mainly described and redundant description will not be repeated here.

<Configuration of Semiconductor Module 100A>

Semiconductor module 100A includes fin base 10, the plurality of fins 20, insulating sheet 30, lead frame 40, semiconductor element 50, wire 60, panel 70, and mold resin 80. In this regard, the configuration of semiconductor module 100A is common to the configuration of semiconductor module 100.

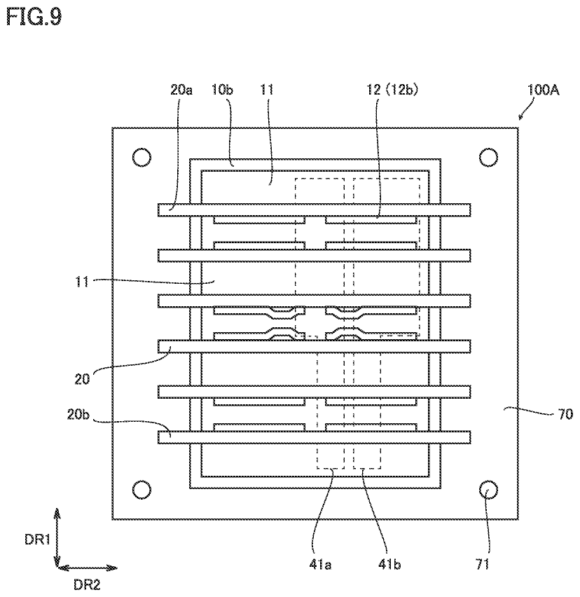

FIG. 9 is a bottom view of semiconductor module 100A. As shown in FIG. 9, in semiconductor module 100A, each of swaging portion 12 adjacent to fin 20a and swaging portion 12 adjacent to fin 20b includes only contact portion 12b (does not include spaced-apart portion 12c). Swaging portion 12 that is not adjacent to fin 20a and fin 20b includes both contact portion 12b and spaced-apart portion 12c. On these points, the configuration of semiconductor module 100A is different from the configuration of semiconductor module 100.

<Method for Manufacturing Semiconductor Module 100A>

A method for manufacturing semiconductor module 100A includes semiconductor element mounting step S1, wire bonding step S2, molding step S3, panel attaching step S4, and swaging step S5. In this regard, the method for manufacturing semiconductor module 100A is common to the method for manufacturing semiconductor module 100.

Tip 210 having the structure shown in FIG. 8 is inserted into groove 12a of swaging portion 12 that is not adjacent to fin 20a and fin 20b. In contrast, tip 210 inserted into each of groove 12a of swaging portion 12 adjacent to fin 20a and groove 12a of swaging portion 12 adjacent to fin 20b does not include second portion 212. As a result, each of swaging portion 12 adjacent to fin 20a and swaging portion 12 adjacent to fin 20b does not include spaced-apart portion 12c. On these points, the method for manufacturing semiconductor module 100A is different from the method for manufacturing semiconductor module 100.

<Effects of Semiconductor Module 100A>

Since fin 20a and fin 20b are fins 20 located on the outermost side in first direction DR1, the fixing force may decrease when the impact is applied. In semiconductor module 100A, each of swaging portion 12 adjacent to fin 20a and swaging portion 12 adjacent to fin 20b does not include spaced-apart portion 12c and a contact area between swaging portion 12 and fin 20 increases, and thus, the resistance to external force is improved.

### Third Embodiment

A semiconductor module according to a third embodiment (hereinafter, referred to as “semiconductor module 100B”) will be described below. A difference from semiconductor module 100 will be mainly described and redundant description will not be repeated here.

Semiconductor module 100B includes fin base 10, the plurality of fins 20, insulating sheet 30, lead frame 40, semiconductor element 50, wire 60, panel 70, and mold resin 80. In this regard, the configuration of semiconductor module 100B is common to the configuration of semiconductor module 100.

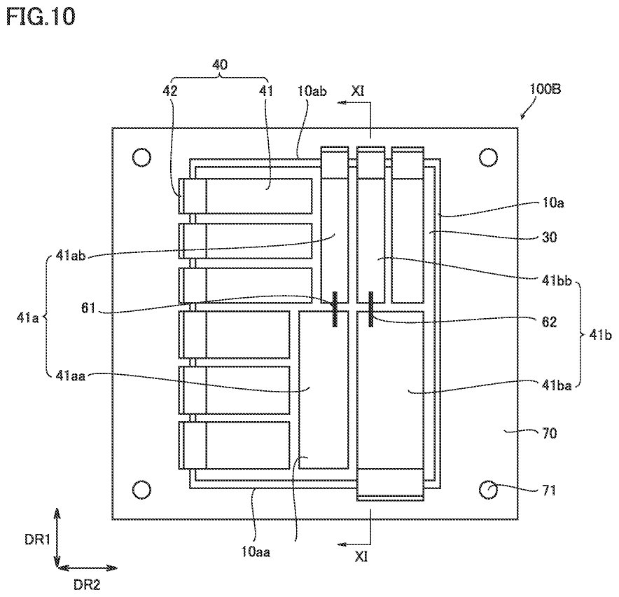

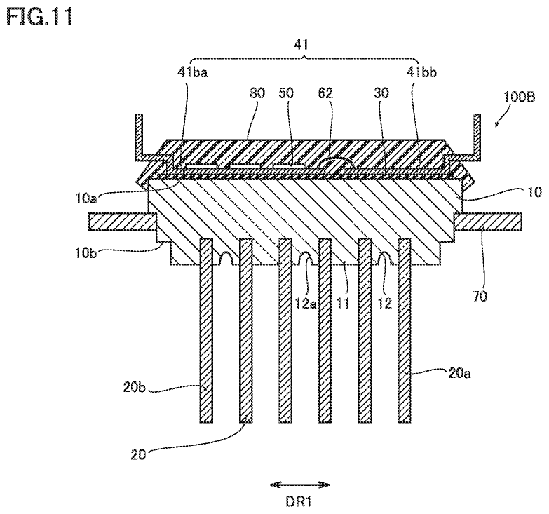

FIG. 10 is a plan view of semiconductor module 100B. In FIG. 10, semiconductor element 50, wire 60 and mold resin 80 are not shown. FIG. 11 is a cross-sectional view taken along XI-XI in FIG. 10. As shown in FIGS. 10 and 11, frame pattern 41a is divided into a first divided frame pattern 41aa and a second divided frame pattern 41ab in first direction DR1. Frame pattern 41b is divided into a first divided frame pattern 41ba and a second divided frame pattern 41bb in first direction DR1.

The division of frame pattern 41a is performed at a central portion of frame pattern 41a in first direction DR1. The division of frame pattern 41b is performed at a central portion of frame pattern 41b in first direction DR1.

First divided frame pattern 41aa and second divided frame pattern 41ab are connected by a wire 61. First divided frame pattern 41ba and second divided frame pattern 41bb are connected by a wire 62. Each of wire 61 and wire 62 is made of, for example, a metal material. Examples of the metal material include aluminum, aluminum alloy, copper, copper alloy, gold and the like.

Wire 61 is arranged at a position that overlaps with spaced-apart portion 12c in a plan view. Wire 62 is arranged at a position that overlaps with contact portion 12b in a plan view. A loop height of each of wire 61 and wire 62 is preferably as low as possible in order to reduce an amount of mold resin 80. Each of wire 61 and wire 62 has, for example, a round shape, a ribbon shape or the like.

First divided frame pattern 41aa and second divided frame pattern 41ab are spaced apart from each other in first direction DR1. Wire 61 extends over this space in a plan view. First divided frame pattern 41ba and second divided frame pattern 41bb are spaced apart from each other in first direction DR1. Wire 62 extends over this space in a plan view.

First divided frame pattern 41aa and second divided frame pattern 41ab perform an electrical function similar to that of frame pattern 41a that is not divided, and first divided frame pattern 41ba and second divided frame pattern 41bb perform an electrical function similar to that of frame pattern 41b that is not divided. On these points, the configuration of semiconductor module 100B is different from the configuration of semiconductor module 100.

<Method for Manufacturing Semiconductor Module 100B>

A method for manufacturing semiconductor module 100A includes semiconductor element mounting step S1, wire bonding step S2, molding step S3, panel attaching step S4, and swaging step S5. In this regard, the method for manufacturing semiconductor module 100A is common to the method for manufacturing semiconductor module 100.

In the method for manufacturing semiconductor module 100B, not only wire bonding by wire 60 but also wire bonding by wire 61 and wire 62 is performed in wire bonding step S2. In this regard, the method for manufacturing semiconductor module 100B is different from the method for manufacturing semiconductor module 100.

<Effects of Semiconductor Module 100B>

In semiconductor module 100B, frame pattern 41a (frame pattern 41b) is divided, and thus, the stress that occurs at the end of frame pattern 41a due to flattening, during swaging, of a warp caused by heat shrinkage and the like of mold resin 80 is further reduced. Therefore, according to semiconductor module 100B, a deterioration of the insulation property caused by separation of insulating sheet 30 or occurrence of a crack in insulating sheet 30 is further suppressed.

### Fourth Embodiment

A semiconductor module according to a fourth embodiment (hereinafter, referred to as “semiconductor module 100C”) will be described below. A difference from semiconductor module 100 will be mainly described and redundant description will not be repeated here.

Semiconductor module 100C includes fin base 10, the plurality of fins 20, insulating sheet 30, lead frame 40, semiconductor element 50, wire 60, panel 70, and mold resin 80. In this regard, the configuration of semiconductor module 100C is common to the configuration of semiconductor module 100.

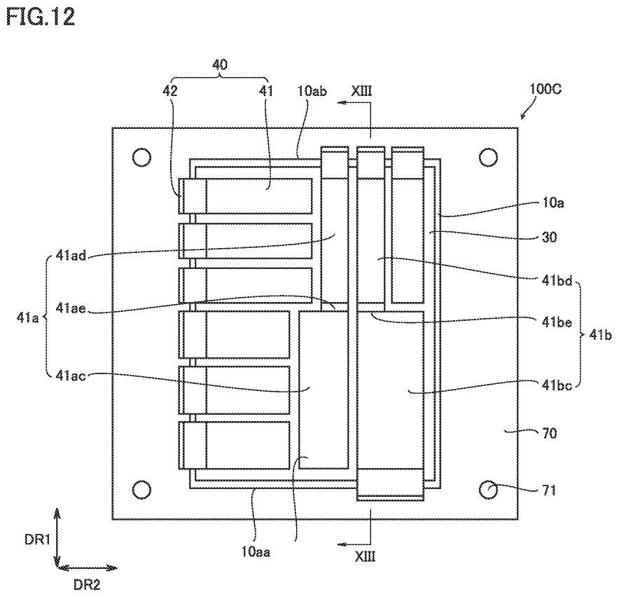

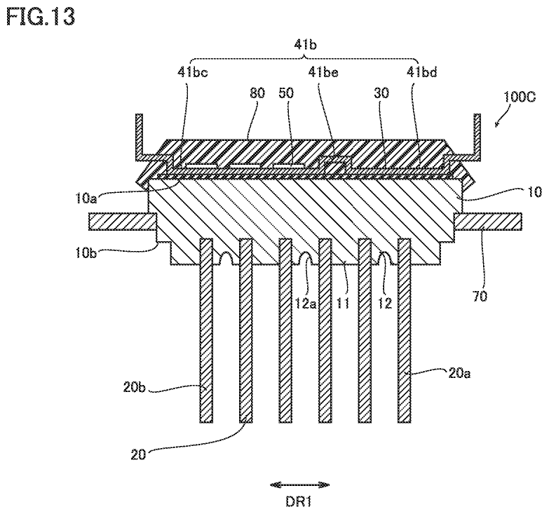

FIG. 12 is a plan view of semiconductor module 100C. In FIG. 12, semiconductor element 50, wire 60 and mold resin 80 are not shown. FIG. 13 is a cross-sectional view taken along XIII-XIII in FIG. 12. As shown in FIGS. 12 and 13, frame pattern 41a includes a first portion 41ac, a second portion 41ad and a step portion 41ae. First portion 41ac and second portion 41ad are aligned along first direction DR1. Step portion 41ae connects first portion 41ac and second portion 41ad. Step portion 41ae protrudes toward the opposite side of first surface 10a. That is, at step portion 41ae, frame pattern 41a is provided with a step having a greater distance from first surface 10a than that of first portion 41ac and second portion 41ad.

Similarly, frame pattern 41b includes a first portion 41bc, a second portion 41bd and a step portion 41be. First portion 41bc and second portion 41bd are aligned along first direction DR1. Step portion 41be connects first portion 41bc and second portion 41bd . Step portion 41be protrudes toward the opposite side of first surface 10a.

That is, at step portion 41be , frame pattern 41b is provided with a step having a greater distance from first surface 10a than that of first portion 41bc and second portion 41bd . On these points, the configuration of semiconductor module 100C is different from the configuration of semiconductor module 100.

<Method for Manufacturing Semiconductor Module 100C>

Since a method for manufacturing semiconductor module 100C is the same as the method for manufacturing semiconductor module 100, description of the method for manufacturing semiconductor module 100C will not be repeated.

<Effects of Semiconductor Module 100C>

In semiconductor module 100C, deformation of frame pattern 41a (frame pattern 41b) is likely to occur at step portion 41ae (step portion 41be ), and the stress that occurs at the end of frame pattern 41a due to flattening, during swaging, of a warp caused by heat shrinkage and the like of mold resin 80 is further reduced. Therefore, a deterioration of the insulation property caused by separation of insulating sheet 30 or occurrence of a crack in insulating sheet 30 is further suppressed.

### Fifth Embodiment

In the present embodiment, the semiconductor module according to any one of the first to fourth embodiments described above is applied to a power conversion device. While the present disclosure is not limited to a specific power conversion device, the case in which the present disclosure is applied to a three-phase inverter will be described below as a fifth embodiment. In the following description, a power conversion system according to the fifth embodiment is referred to as “power conversion system 300”.

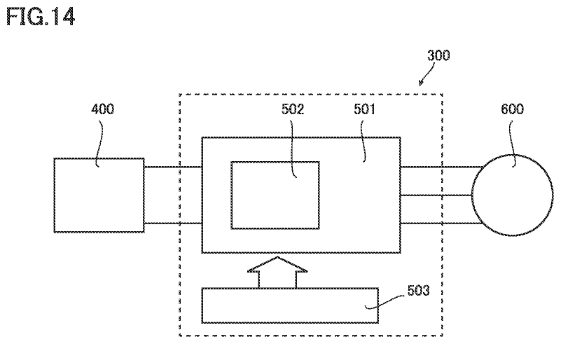

FIG. 14 is a block diagram showing a configuration of power conversion system 300.

The power conversion system shown in FIG. 14 includes a power supply 400, a power conversion device 500 and a load 600. Power supply 400 is a DC power supply and supplies DC power to power conversion device 500. Power supply 400 may be implemented by various components, e.g., a DC system, a solar cell and a storage battery, or may be implemented by a rectifier circuit or an AC/DC converter connected to an AC system. Alternatively, power supply 400 may be implemented by a DC/DC converter that converts DC power supplied from the DC system into predetermined power.

Power conversion device 500 is a three-phase inverter connected between power supply 400 and load 600, and converts DC power supplied from power supply 400 into AC power and supplies the AC power to load 600. As shown in FIG. 14, power conversion device 500 includes a main conversion circuit 501 that converts DC power into AC power and outputs the AC power, and a control circuit 503 that outputs, to main conversion circuit 501, a control signal for controlling main conversion circuit 501.

Load 600 is a three-phase electric motor driven by the AC power supplied from power conversion device 500. Load 600 is not limited to a specific application, and is an electric motor mounted on various electric devices such as a hybrid vehicle, an electric vehicle, a railroad vehicle, an elevator, or an air conditioner.

Details of power conversion device 500 will be described below. Main conversion circuit 501 includes a switching element and a freewheeling diode (not shown), and switching of the switching element causes main conversion circuit 501 to convert the DC power supplied from power supply 400 into AC power and supply the AC power to load 600. Although there are various specific circuit configurations of main conversion circuit 501, main conversion circuit 501 according to the present embodiment is a two-level three-phase full-bridge circuit and can be formed of six switching elements and six freewheeling diodes connected in antiparallel to the switching elements, respectively. At least one of the switching elements and the freewheeling diodes of main conversion circuit 501 is a switching element or a freewheeling diode of a semiconductor module 502 corresponding to the semiconductor module according to any one of the first to fourth embodiments described above. The six switching elements are connected in series in pairs to form upper and lower arms, and each pair of the upper and lower arms forms each phase (U phase, V phase and W phase) of the full-bridge circuit. Output terminals of each pair of the upper and lower arms, i.e., three output terminals of main conversion circuit 501 are connected to load 600.

Although main conversion circuit 501 includes a drive circuit (not shown) that drives each switching element, the drive circuit may be built into semiconductor module 502, or may be provided separately from semiconductor module 502. The drive circuit generates a drive signal for driving each switching element of main conversion circuit 501, and supplies the drive signal to a control electrode of the switching element of main conversion circuit 501. Specifically, in accordance with a below-described control signal from control circuit 503, a drive signal for switching the switching element to the on state and a drive signal for switching the switching element to the off state are output to the control electrode of each switching element. When the switching element is maintained in the on state, the drive signal is a voltage signal (on signal) higher than or equal to a threshold voltage of the switching element. When the switching element is maintained in the off state, the drive signal is a voltage signal (off signal) lower than or equal to the threshold voltage of the switching element.

Control circuit 503 controls the switching elements of main conversion circuit 501 such that desired electric power is supplied to load 600. Specifically, based on the electric power to be supplied to load 600, the time (on time) at which each switching element of main conversion circuit 501 should be turned on is calculated. For example, main conversion circuit 501 can be controlled by PWM control in which the on time of each switching element is modulated in accordance with a voltage to be output. A control command (control signal) is output to the drive circuit of main conversion circuit 501 such that the on signal is output to a switching element that should be turned on and the off signal is output to a switching element that should be turned off at each point in time. In accordance with this control signal, the drive circuit outputs the on signal or the off signal to the control electrode of each switching element as the drive signal.

In power conversion device 500, the semiconductor module according to any one of the first to fourth embodiments described above is applied as semiconductor module 502 that is a component of main conversion circuit 501. Therefore, suppression of a deterioration of the insulation property can be achieved.

Although the example in which the present disclosure is applied to the two-level three-phase inverter has been described in the present embodiment, the present disclosure is not limited thereto and is applicable to various power conversion devices. Although the present disclosure is applied to the two-level power conversion device in the present embodiment, the present disclosure may be applied to a three-level or multi-level power conversion device, or may be applied to a single-phase inverter when electric power is supplied to a single-phase load. The present disclosure is also applicable to a DC/DC converter or an AC/DC converter when electric power is supplied to a DC load or the like.

In addition, the power conversion device to which the present disclosure is applied is not limited to the above-described case in which the load is an electric motor, and can also be used, for example, as a power supply device for an electric discharge machine, a laser processing machine, an induction heating cooker, or a wireless power feeding system. Furthermore, the power conversion device to which the present disclosure is applied can also be used as a power conditioner for a photovoltaic power generation system, a power storage system or the like.

It should be understood that the embodiments disclosed herein are illustrative and non-restrictive in every respect. The basic scope of the present disclosure is defined by the terms of the claims, rather than the embodiments above, and is intended to include any modifications within the scope and meaning equivalent to the terms of the claims.

### REFERENCE SIGNS LIST

10 fin base; 10a first surface; 10aa first end; 10ab second end; 10b second surface; 11 rising wall portion; 12 swaging portion; 12a groove; 12b contact portion; 12c spaced-apart portion; 20 fin; 20a fin; 20b fin; 30 insulating sheet; 40 lead frame; 41 frame pattern; 41a frame pattern; 41aa first divided frame pattern; 41ab second divided frame pattern; 41ac first portion; 41ad second portion; 41ae step portion; 41b frame pattern; 41ba first divided frame pattern; 41bb second divided frame pattern; 41bc first portion; 41bd second portion; 41be step portion; 41c first surface; 41d second surface; 41e side surface; 41f corner portion; 42 terminal portion; 50 semiconductor element; 60 wire; 61 wire; 62 wire; 70 panel; 71 hole; 80 mold resin; 100 semiconductor module; 100A semiconductor module; 100B semiconductor module; 100C semiconductor module; 200 swaging blade; 210 tip; 211 first portion; 212 second portion; 220 punch; 300 power conversion system; 400 power supply; 500 power conversion device; 501 main conversion circuit; 502 semiconductor module; 503 control circuit; 600 load; DR1 first direction; DR2 second direction; 51 semiconductor element mounting step; S2 wire bonding step; S3 molding step; S4 panel attaching step; S5 swaging step.

1. A semiconductor module comprising:
a fin base including a first surface and a second surface, the second surface being a surface opposite to the first surface;
an insulating sheet arranged on the first surface;
a plurality of frame patterns arranged on the first surface with the insulating sheet interposed therebetween;
a semiconductor element arranged on at least one of the plurality of frame patterns; and
a plurality of fins swaged onto the second surface so as to be spaced apart from each other in a first direction, wherein
the second surface is provided with a plurality of rising wall portions and a plurality of swaging portions, the plurality of rising wall portions extending along a second direction that intersects with the first direction and being spaced apart from each other in the first direction, each of the plurality of swaging portions extending along the second direction between adjacent two of the plurality of rising wall portions,
at least one of the plurality of swaging portions includes a contact portion and a spaced-apart portion, the contact portion being in contact with a corresponding one of the plurality of fins, the spaced-apart portion being spaced apart from the corresponding one of the plurality of fins.
the first direction is along a longitudinal direction of the fin base,
the first surface includes a first end and a second end in the first direction the second end being an end opposite to the first end,
the plurality of frame patterns include a first frame pattern and a second frame pattern extending along the first direction and being spaced apart from each other in the second direction on a central portion of the first surface,
both ends of each of the first frame pattern and the second frame pattern are located outside a first fin of the plurality of fins located closest to the first end and a second fin of the plurality of fins located closest to the second end, and
the spaced-apart portion is arranged at a position that overlaps with a space between the first frame pattern and the second frame pattern, wen viewed from a direction orthogonal to the first surface.

2. (canceled)

3. The semiconductor module according to claim 1, wherein
a first swaging portion and a second swaging portion of the plurality of swaging portions are adjacent to the first fin and the second fin, respectively, and include only the contact portion.

4. The semiconductor module according to claim 1, further comprising a wire, wherein
the first frame pattern is divided into a first divided frame pattern and a second divided frame pattern in the first direction, and
the first divided frame pattern and the second divided frame pattern are connected by the wire.

5. The semiconductor module according to claim 1, wherein
the first frame pattern includes a first portion, a second portion, and a step portion connecting the first portion and the second portion and protruding toward an opposite side of the first surface.

6. The semiconductor module according to claim 1, wherein
a first length is longer than a second length, the first length being a length of the contact portion in the second direction, the second length being a length of the spaced-apart portion in the second direction.

7. The semiconductor module according to claim 6, wherein
a value obtained by dividing the second length by the first length is not less than 0.3 and not more than 0.6.

8. A power conversion device comprising:
a main conversion circuit including the semiconductor module as recited in claim 1, to convert input electric power and output the input electric power; and
a control circuit to output, to the main conversion circuit, a control signal for controlling the main conversion circuit.

9. A method for manufacturing a semiconductor module, the method comprising:
arranging a semiconductor element on at least one of a plurality of frame patterns;
arranging the plurality of frame patterns on a first surface of a fin base with an insulating sheet interposed therebetween, the insulating sheet being arranged on the first surface; and
swaging a plurality of fins on a second surface such that the plurality of fins are spaced apart from each other in a first direction, the second surface being a surface opposite to the first surface, wherein
the second surface is provided with a plurality of rising wall portions and a plurality of swaging portions, the plurality of rising wall portions extending along a second direction that intersects with the first direction and being spaced apart from each other in the first direction, each of the plurality of swaging portions extending along the second direction between adjacent two of the plurality of rising wall portions,
an upper surface of each of the plurality of swaging portions is provided with a groove extending along the second direction,
the swaging a plurality of fins is performed by inserting a tip of a swaging blade into the groove and expanding a width of the groove along the first direction,-
the tip includes a first portion having a width in the first direction larger than the width of the groove, and a second portion having a width in the first direction smaller than the width of the groove,
the first direction is along a longitudinal direction of the fin base,
the first surface includes a first end and a second end in the first direction, the second end being an opposite to the first end,
the plurality of frame patterns include a first frame pattern and a second frame pattern extending along the first direction and being spaced apart from each other in the second direction on a central portion of the first surface,
both ends of each of the first frame pattern and the second frame pattern are located outside a first fin of the plurality of fins located closest to the first end and a second fin of the plurality of fins located closest to the second end, and
the spaced-apart portion is arranged at a position that overlaps with a space between the first frame pattern and the second frame pattern, when viewed from a direction orthogonal to the first surface.
